(19) United States
(12) Patent Application Publication
(10) Pub. No.: US 2024/0416450 A1
(43) Pub. Date: Dec. 19, 2024

(54) PROCESSING METHOD AND PROCESSING SYSTEM

(71) Applicant: Tokyo Electron Limited, Tokyo (JP)

(72) Inventors: Kazuya HISANO, Koshi City, Kumamoto (JP); Yoshihiro KAWAGUCHI, Kikuchi-gun, Kumamoto (JP); Gousuke SHIRAISHI, Kikuchi-gun, Kumamoto (JP)

(21) Appl. No.: 18/706,115

(22) PCT Filed: Oct. 19, 2022
(86) PCT No.: PCT/JP2022/038885

§ 371 Date: Apr. 30, 2024

(30) Foreign Application Priority Data
Nov. 2, 2021 (JP) 2021-179529

(51) Int. Cl. B23K 26/03; B23K 26/53; B23K 101/40; G06T 7/00; G06T 7/11; H01L 21/02

(52) U.S. Cl. CPC B23K 26/032; B23K 26/53; G06T 7/0004; G06T 7/11; H01L 21/02021; B23K 2101/40; G06T 2207/30148

(57) ABSTRACT

A processing method of processing a combined substrate in which a first substrate and a second substrate are bonded to each other includes: forming, by radiating interface laser light to an interface between the first substrate and the second substrate, a non-bonding region with reduced bonding strength at the interface; inspecting a forming state of the non-bonding region; forming a peripheral modification layer along a boundary between a peripheral portion and a central portion of the first substrate; and removing the peripheral portion starting from the peripheral modification layer. The inspecting of the forming state of the non-bonding region includes: imaging the non-bonding region with a camera; acquiring, from an obtained image of the non-bonding region, a distribution of gray values in a plan view of the non-bonding region; and inspecting the forming state of the non-bonding region by comparing the acquired gray values with a preset threshold value.

### TECHNICAL FIELD

The various aspects and embodiments described herein pertain generally to a processing method and a processing system.

### BACKGROUND

Patent Document 1 describes a substrate processing system including a modification layer forming apparatus configured to form a modification layer inside a first substrate along a boundary between a central portion and a to-be-removed peripheral portion of the first substrate in a combined substrate in which the first substrate and a second substrate are bonded to each other; and a periphery removing apparatus configured to remove the peripheral portion of the first substrate, starting from the modification layer.

### PRIOR ART DOCUMENT

Patent Document 1: International Publication No. 2019/176589

### DISCLOSURE OF THE INVENTION

### Problems to be Solved by the Invention

Exemplary embodiments provide a technique enabling appropriate removal of a peripheral portion of a first substrate in a combined substrate in which the first substrate and a second substrate are bonded to each other.

### Means for Solving the Problems

In an exemplary embodiment, a processing method of processing a combined substrate in which a first substrate and a second substrate are bonded to each other includes: forming, by radiating interface laser light to an interface between the first substrate and the second substrate, a non-bonding region with reduced bonding strength at the interface; inspecting a forming state of the non-bonding region; forming a peripheral modification layer along a boundary between a peripheral portion of the first substrate and a central portion of the first substrate; and removing the peripheral portion starting from the peripheral modification layer. The inspecting of the forming state of the non-bonding region includes: imaging the non-bonding region by using a camera; acquiring, from an obtained image of the non-bonding region, a distribution of gray values in a plan view of the non-bonding region; and inspecting the forming state of the non-bonding region by comparing the acquired gray values with a preset threshold value.

### Effect of the Invention

According to the exemplary embodiments, it is possible to appropriately remove the peripheral portion of the first substrate in the combined substrate in which the first substrate and the second substrate are bonded to each other.

### BRIEF DESCRIPTION OF THE DRAWINGS

FIG. 1 is a side view illustrating an example structure of a combined wafer to be processed.

FIG. 2 is a plan view illustrating a schematic configuration of a wafer processing system according to an exemplary embodiment.

FIG. 3 is a transversal cross sectional view illustrating a non-bonding region, a peripheral modification layer, and a split modification layer formed in the combined wafer.

FIG. 4 is a plan view illustrating a schematic configuration of an interface modifying apparatus and an internal modifying apparatus.

FIG. 5 is a side view illustrating a schematic configuration of the interface modifying apparatus and the internal modifying apparatus.

FIG. 6A to FIG. 6C are explanatory diagrams illustrating main processes of a wafer processing in the wafer processing system.

FIG. 7 is a flowchart illustrating the main processes of the wafer processing in the wafer processing system.

FIG. 8 is an explanatory diagram illustrating main processes of inspection in the interface modifying apparatus.

FIG. 9 is an explanatory diagram illustrating the main processes of the inspection in the interface modifying apparatus.

FIG. 10 is a flowchart illustrating the main processes of the inspection in the interface modifying apparatus.

FIG. 11 is an explanatory diagram illustrating inspection being performed in the internal modifying apparatus.

FIG. 12 is an explanatory diagram illustrating the inspection being performed in the internal modifying apparatus.

FIG. 13 is an explanatory diagram illustrating the inspection being performed in the internal modifying apparatus.

FIG. 14 is an explanatory diagram illustrating the inspection being performed in the internal modifying apparatus.

FIG. 15 is an explanatory diagram illustrating the inspection being performed in the internal modifying apparatus.

FIG. 16 is a flowchart illustrating the main processes of the inspection in the internal modifying apparatus.

FIG. 17 is an explanatory diagram illustrating another example of forming a peripheral modification layer inside a first wafer.

FIG. 18 is an explanatory diagram illustrating inspection being performed in the periphery removing apparatus.

FIG. 19 is an explanatory diagram illustrating the inspection being performed in the periphery removing apparatus.

FIG. 20 is an explanatory diagram illustrating the inspection being performed in the periphery removing apparatus.

FIG. 21 is an explanatory diagram illustrating the inspection being performed in the periphery removing apparatus.

FIG. 22 is an explanatory diagram illustrating the inspection being performed in the periphery removing apparatus.

FIG. 23 is a flowchart illustrating main processes of the inspection in the periphery removing apparatus.

### DETAILED DESCRIPTION

In a manufacturing process for a semiconductor device, in a combined substrate in which a first substrate (a silicon substrate such as semiconductor) having devices such as a plurality of electronic circuits formed on a front surface thereof and a second substrate are bonded to each other, removal of a peripheral portion of the first wafer, so-called edge trimming may be performed.

The edge trimming of the first substrate is performed by using a substrate processing system described in, for example, Patent Document 1. That is, a modification layer is formed by radiating laser light to an inside of the first substrate, and the peripheral portion of the first substrate is removed starting from the modification layer. Further, according to the substrate processing system disclosed in Patent Document 1, by radiating laser light to an interface at which the first substrate and the second substrate are bonded, a modification surface is formed to reduce bonding strength between the first substrate and the second substrate at the peripheral portion thus enabling the appropriate removal of the peripheral portion.

However, when forming the modification layer for reducing the bonding strength at the interface where the first substrate and the second substrate are bonded, there is a risk that the modification surface may not be appropriately formed on the entire surface of the peripheral portion to be removed due to various factors such as, by way of example, axial deviation of the laser light or the like. When the modification surface cannot be formed on the entire peripheral portion for these factors, for example, when the modification surface is not formed in a part of a circumferential direction or when the width of the modification surface thus formed is not uniform around the entire circumference, a part of the peripheral portion of the first substrate to be removed may remain on the center side of the first substrate, which may cause generation of particles or the like in the subsequent process.

In view of the foregoing, exemplary embodiments provide a technique enabling appropriate the removal of the peripheral portion of the first substrate in the combined substrate in which the first substrate and the second substrate are bonded to each other. Hereinafter, a wafer processing system as a processing system and a wafer processing method as a processing method according to exemplary embodiments will be described with reference to the accompanying drawings. In the present specification and the drawings, parts having substantially the same functions and configurations will be assigned same reference numerals, and redundant description thereof will be omitted.

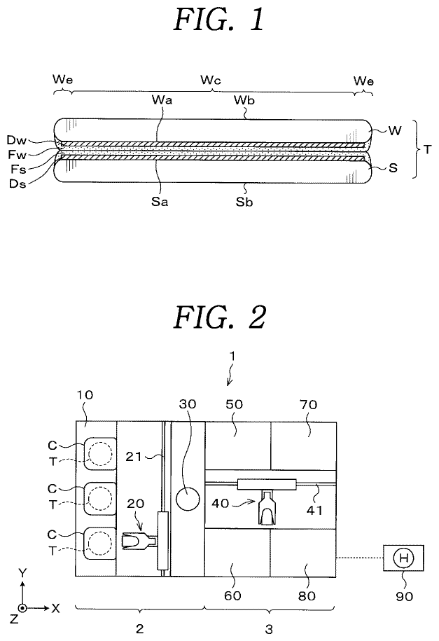

In a wafer processing system 1 to be described later according to the present exemplary embodiment, a processing is performed on a combined wafer T as a combined substrate in which a first wafer W as a first substrate and a second wafer S as a second substrate are bonded to each other as shown in FIG. 1. Hereinafter, in the first wafer W, a surface bonded to the second wafer S is referred to as a front surface Wa, and a surface opposite to the front surface Wa is referred to as a rear surface Wb. Likewise, in the second wafer S, a surface bonded to the first wafer W is referred to as a front surface Sa, and a surface opposite to the front surface Sa is referred to as a rear surface Sb.

The first wafer W is, for example, a semiconductor wafer such as a silicon substrate, and a device layer Dw including a plurality of devices is formed on the front surface Wa thereof. Further, a bonding film Fw is further formed on the device layer Dw, and the first wafer W is bonded to the second wafer S with the bonding film Fw therebetween. An oxide film (a THOX film, a SiO₂ film, a TEOS film, etc.), a SiC film, a SiCN film, or an adhesive is used as an example of the bonding film Fw. Further, a peripheral portion We of the first wafer W is chamfered, and the thickness of this peripheral portion We decreases toward a leading end thereof on a cross section thereof. Furthermore, the peripheral portion We is a portion to be removed in edge trimming to be described later, and is in the range of 0.5 mm to 3 mm from an edge of the first wafer W in a radial direction. In the following description, a portion of the first wafer W, which is inner side than the peripheral portion We to be removed in the radial direction, will sometimes be referred to as a central portion Wc.

The second wafer S has, for example, the same structure as the first wafer W. A device layer Ds and a bonding film Fs are formed on the front surface Sa, and a peripheral portion of the second wafer S is chamfered. However, the second wafer S does not need to be a device wafer on which the device layer Ds is formed, but it may be, for example, a support wafer that supports the first wafer W. In this case, the second wafer S functions as a protective member that protects the device layer Dw of the first wafer W.

As depicted in FIG. 2, the wafer processing system 1 has a configuration in which a carry-in/out station 2 and a processing station 3 are connected as one body. In the carry-in/out station 2, a cassette C capable of accommodating therein a plurality of combined wafers T is carried to/from the outside, for example. The processing station 3 is equipped with various types of processing apparatuses configured to perform required processings on the combined wafer T.

The carry-in/out station 2 is equipped with a cassette placing table 10 on which the cassette C capable of accommodating therein the plurality of combined wafers T is placed. Further, a wafer transfer device 20 is provided adjacent to the cassette placing table 10 on the positive X-axis side of the cassette placing table 10. The wafer transfer device 20 is configured to be moved on a transfer path 21 extending in the Y-axis direction to transfer the combined wafer T between the cassette C of the cassette placing table 10 and a transition device 30 to be described later.

In the carry-in/out station 2, the transition device 30 configured to deliver the combined wafer T and the like to/from the processing station 3 is provided adjacent to the wafer transfer device 20 on the positive X-axis side of the wafer transfer device 20.

Disposed in the processing station 3 are a wafer transfer device 40, an interface modifying apparatus 50, an internal modifying apparatus 60, a periphery removing apparatus 70, and a cleaning apparatus 80.

The wafer transfer device 40 is provided on the positive X-axis side of the transition device 30. The wafer transfer device 40 is configured to be movable on a transfer path 41 extending in the X-axis direction to transfer the combined wafer T to/from the transition device 30 of the carry-in/out station 2, the interface modifying apparatus 50, the internal modifying apparatus 60, the periphery removing apparatus 70 and the cleaning apparatus 80.

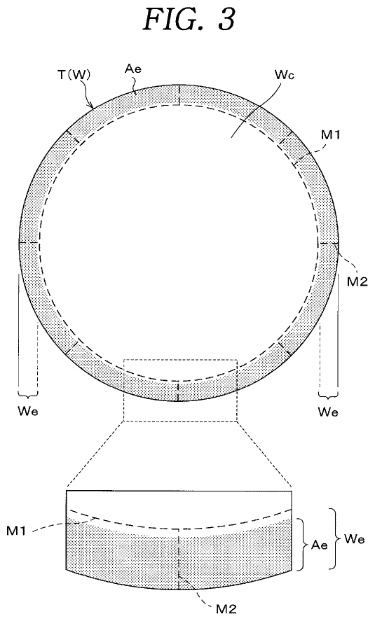

The interface modifying apparatus 50 is configured to radiate laser light (interface laser light such as a CO₂ laser) to an interface between the first wafer W and the second wafer S to form, in the peripheral portion We to be removed, a non-bonding region Ae (see FIG. 3) in which bonding strength between the first wafer W and the second wafer S is reduced.

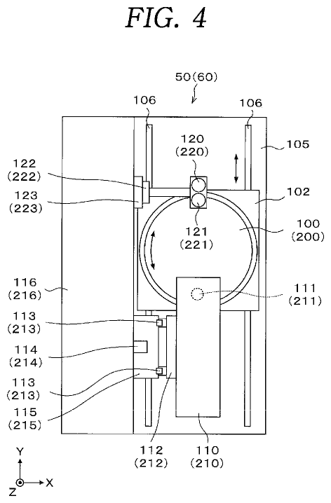

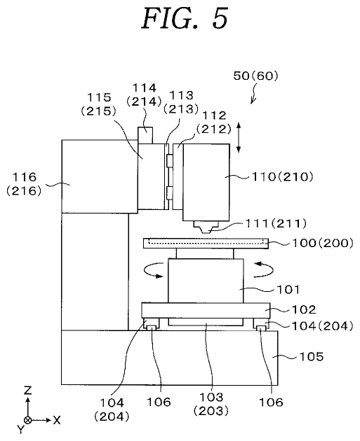

As depicted in FIG. 4 and FIG. 5, the interface modifying apparatus 50 has a chuck 100 configured to hold the combined wafer T on a top surface thereof. The chuck 100 attracts and holds the rear surface Sb of the second wafer S with the first wafer W positioned on the upper side and the second wafer S positioned on the lower side. The chuck 100 is supported by a slider table 102 with an air bearing 101 therebetween. A rotating mechanism 103 is provided on a bottom surface of the slider table 102. The rotating mechanism 103 has, for example, a motor as a driving source embedded therein. The chuck 100 is configured to be rotatable around a vertical axis by the rotating mechanism 103 via the air bearing 101. The slider table 102 is configured to be movable on a rail 106 extending on a base 105 in the Y-axis direction by a moving mechanism 104 provided on a bottom surface thereof. Further, although not particularly limited, a driving source of the moving mechanism 104 may be, by way of example, a linear motor.

A laser head 110 is disposed above the chuck 100. The laser head 110 has a lens 111. The lens 111 is a cylindrical member provided on a bottom surface of the laser head 110, and is configured to radiate the interface laser light to an inside of the combined wafer T held by the chuck 100, more specifically, to the interface between the first wafer W and the second wafer S. As a result, the inside portion of the combined wafer T irradiated with the interface laser light is modified, so that the non-bonding region Ae in which the bonding strength between the first wafer W and the second wafer S is reduced is formed. Furthermore, in the technology according to the present disclosure, the “interface between the first wafer W and the second wafer S” is assumed to include interfaces and insides of the first wafer W, the device layers Dw and Ds, the bonding films Fw and Fs, and the second wafer S as well. In other words, the position where the non-bonding region Ae is formed is not particularly limited as long as the bonding strength between the first wafer W and the second wafer S can be reduced.

The laser head 110 is supported by a supporting member 112. The laser head 110 is configured to be movable up and down by an elevating mechanism 114 along a rail 113 extending in a vertical direction. Further, the laser head 110 is also configured to be movable in the Y-axis direction by a moving mechanism 115. Each of the elevating mechanism 114 and the moving mechanism 115 is supported on a supporting column 116.

Above the chuck 100, a macro camera 120 and a micro camera 121 are disposed on the positive Y-axis side of the laser head 110. For example, the macro camera 120 and the micro camera 121 are configured as one body, and the macro camera 120 is disposed on the positive Y-axis side of the micro camera 121. The macro camera 120 and the micro camera 121 are configured to be movable up and down by an elevating mechanism 122, and are also configured to be movable in the Y-axis direction by a moving mechanism 123. The moving mechanism 123 is supported on the supporting column 116.

The macro camera 120 is configured to image an outer end of the first wafer W (combined wafer T). As an example, the image taken by the macro camera 120 is used to align the first wafer W, which will be described later. The macro camera 120 has, for example, a coaxial lens; radiates light capable of penetrating at least the first wafer W, for example, infrared light (IR); and receives reflection light from a target object. Additionally, the macro camera 120 has an imaging magnification of 2 times.

The micro camera 121 is configured to image the non-bonding region Ae formed at the interface between the first wafer W and the second wafer S. The image taken by the micro camera 121 is used to detect whether the non-bonding region Ae has been formed appropriately, for example. The micro camera 121 has, for example, a coaxial lens; radiates light capable of penetrating at least the first wafer W, for example, infrared light (IR); and receives reflection light from a target object. The micro camera 121 has an imaging magnification of 10 times, a field of view of about ⅕ of that of the macro camera 120, and a pixel size of about ⅕ of that of the macro camera 120.

In the present exemplary embodiment, the macro camera 120 and the micro camera 121 are disposed as shown in the drawing to image the non-bonding region Ae formed at the interface between the first wafer W and the second wafer S. In this way, by adopting the configuration in which the non-bonding region Ae is imaged by the micro camera 121 having the higher imaging magnification, it is possible to detect the non-bonding region Ae with higher precision as compared to a case where the non-bonding region Ae is imaged by the macro camera 120.

Further, in the present exemplary embodiment, although both the macro camera 120 and the micro camera 121 are used as shown in the drawing, the macro camera 120 may be omitted when the outer end of the first wafer W can be appropriately imaged by using the micro camera 121.

Moreover, in the shown example, the chuck 100 is configured to be rotated and horizontally moved relative to the laser head 110 by the rotating mechanism 103 and the moving mechanism 104. However, the laser head 110 may be configured to be rotated and horizontally moved relative to the chuck 100. Still alternatively, both the chuck 100 and the laser head 110 may be configured to be rotatable and horizontally movable relative to each other.

The internal modifying apparatus 60 is configured to radiate laser light (internal laser light such as a YAG laser) to an inside of the first wafer W to form a peripheral modification layer M1 serving as a starting point for separation of the peripheral portion We and a split modification layer M2 serving as a starting point for breaking the peripheral portion We into smaller pieces (see FIG. 3).

The configuration of the internal modifying apparatus 60 is not particularly limited. As an example, the internal modifying apparatus 60 has the same configuration as the interface modifying apparatus 50. That is, as shown in FIG. 4, the internal modifying apparatus 60 includes a chuck 200 configured to hold the combined wafer T on a top surface thereof; a laser head 210 configured to radiate the internal laser light to an inside of the first wafer W held by the chuck 200; and a macro camera 220 and a micro camera 221 configured to image the combined wafer T held by the chuck 200.

The laser head 210 is provided with a lens 211. Further, the laser head 210 is configured to be movable by a supporting member 212, a rail 213, an elevating mechanism 214, and a moving mechanism 215. Each of the elevating mechanism 214 and the moving mechanism 215 is supported on a supporting column 216.

The macro camera 220 and the micro camera 221 are configured to be movable by an elevating mechanism 222 and a moving mechanism 223. The moving mechanism 223 is supported on the supporting column 216.

The chuck 200 and the laser head 210 are configured to be rotatable and horizontally movable relative to each other by, for example, a rotating mechanism 203 and a moving mechanism 204. The laser head 210 has a lens 211 configured to radiate the internal laser light to the inside of the first wafer W held by the chuck 200.

The macro camera 220 is configured to image the outer end of the first wafer W (combined wafer T). The image taken by the macro camera 220 is used to, for example, align the first wafer W, which will be described later.

The micro camera 221 is configured to image the vicinity of the peripheral portion We of the first wafer W, more specifically, the range from the outer end of the first wafer W to a slightly inner side than the target formation position of the peripheral modification layer M1 in the radial direction (up to an outer end of the central portion Wc of the first wafer W remaining in the combined wafer T after the edge trimming). The image obtained by the micro camera 221 is used to detect whether the peripheral modification layer M1 has been appropriately formed inside the first wafer W, for example.

The periphery removing apparatus 70 is configured to perform the removal of the peripheral portion We of the first wafer W starting from the peripheral modification layer M1 formed in the internal modifying apparatus 60, that is, the edge trimming. A method of the edge trimming is not particularly limited. As an example, in the periphery removing apparatus 70, a blade formed in a wedge shape, for example, may be inserted. As another example, air or a water jet may be blown toward the peripheral portion We to apply an impact to the peripheral portion We.

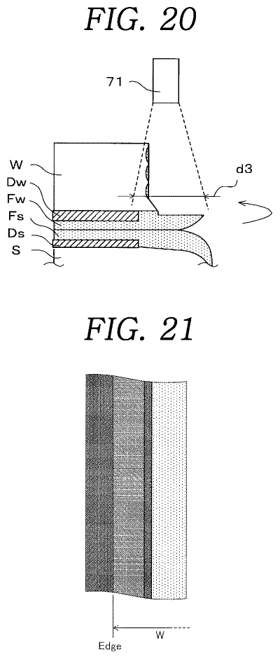

Furthermore, the periphery removing apparatus 70 may image the peripheral portion of the combined wafer T after being subjected to the removal of the peripheral portion We by using an imaging mechanism 71 (see FIG. 20) to detect whether the peripheral portion We has been appropriately removed from the first wafer W. In this case, a CCD camera, for example, may be adopted as the imaging mechanism 71.

The cleaning apparatus 80 is configured to perform a cleaning processing on the first wafer W and the second wafer S after being subjected to the edge trimming in the periphery removing apparatus 70 to remove particles on these wafers. A method of the cleaning is not particularly limited.

The wafer processing system 1 described above is provided with a control device 90. The control device 90 is, for example, a computer, and has a program storage (not shown). The program storage stores therein a program for controlling the processing for the combined wafer T in the wafer processing system 1. In addition, the program storage also stores therein a program for controlling the operations of the driving systems including the transfer devices and the various processing apparatuses described above to implement a wafer processing to be described later in the wafer processing system 1. The programs may have been recorded on a computer-readable recording medium H, and may be installed from the recording medium H into the control device 90. Further, the recording medium H may be transitory or non-transitory.

Now, a wafer processing performed by using the wafer processing system 1 configured as described above will be explained. In the present exemplary embodiment, the first wafer W and the second wafer S are bonded in advance to form the combined wafer T.

First, the cassette C accommodating therein a plurality of combined wafers T is placed on the cassette placing table 10 of the carry-in/out station 2. Then, the combined wafer T in the cassette C is taken out by the wafer transfer device 20, and transferred to the interface modifying apparatus 50 via the transition device 30 and the wafer transfer device 40.

In the interface modifying apparatus 50, the combined wafer T held by the chuck 100 is first moved to a macro imaging position. The macro imaging position is a position where the macro camera 120 is capable of imaging the outer end of the first wafer W. At the macro imaging position, while rotating the chuck 100, the macro camera 120 images the outer end of the first wafer W in 360 degrees in the circumferential direction thereof. The obtained image is outputted from the macro camera 102 to the control device 90.

The control device 90 calculates an eccentric amount between a rotation center of the chuck 100 and a center of the first wafer W from the image of the macro camera 120. Also, the control device 90 calculates a moving amount of the chuck 100 based on the calculated eccentric amount to correct a Y-axis component of the corresponding eccentric amount. The control device 90 moves the chuck 100 horizontally along the Y-axis direction based on this calculated moving amount.

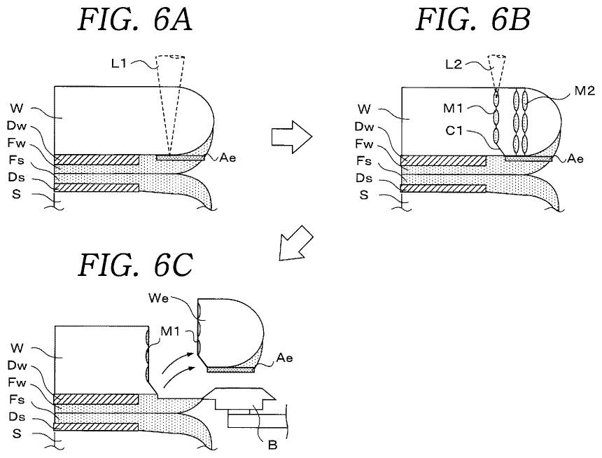

Next, the interface laser light L1 is radiated in a pulse shape from the laser head 110 to a preset radiation area of the interface laser light L1 to modify the interface between the first wafer W and the second wafer S (the interface between the first wafer W and the bonding film Fw in the shown example) as shown in FIG. 3 and FIG. 6A. In the present exemplary embodiment, the “modification of the interface” is assumed to include, as an example, amorphization of the device layer Dw or the bonding film Fw at the radiation position of the interface laser light L1, separation of the first wafer W and the second wafer S, and so forth. In addition, the interface between the first wafer W and the second wafer S where the non-bonding region Ae is formed is not limited to the shown example, and the non-bonding region Ae may be formed at any position inside the combined wafer T as long as the bonding strength between the first wafer W and the second wafer S can be reduced.

For example, the radiation area of the interface laser light L1 is set to an annular region having a required width in the radial direction from the outer end of the first wafer W. The width of the radiation area in the radial direction is set to a width allowing appropriate removal of the peripheral portion We of the first wafer W to be removed. The position of the outer end of the first wafer W, which serves as a reference, may be determined in advance based on an alignment position accompanying the movement of the chuck 100 in the Y-axis direction, or may be acquired based on the imaging result by the macro camera 120 as described above.

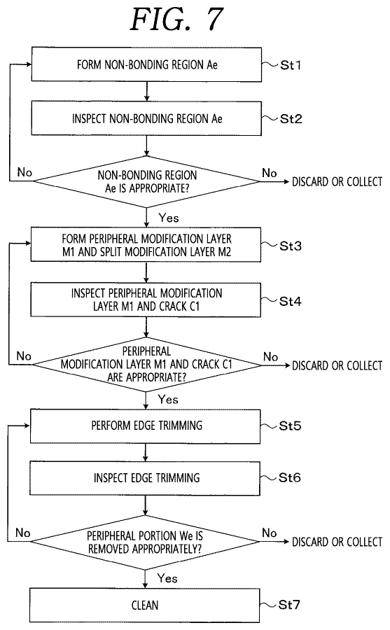

In the interface modifying apparatus 50, by modifying the radiation position of the interface laser light L1 at the interface between the first wafer W and the second wafer S in this way, the non-bonding region Ae in which the bonding strength between the first wafer W and the second wafer S is reduced is formed (process St1 in FIG. 7). In the edge trimming to be described later, the peripheral portion We of the first wafer W, which is a target to be removed, is removed. The presence of the non-bonding region Ae enables appropriate removal of the peripheral portion We.

Once the non-bonding region Ae is formed at the interface between the first wafer W and the second wafer S, it is inspected whether or not the non-bonding region Ae has been appropriately formed at the interface (process St2 in FIG. 7). A detailed inspection method in the interface modifying apparatus 50 will be described later.

If it is determined in the process St2 that the non-bonding region Ae is not properly formed, that is, when it is determined that the width of the formed non-bonding region Ae is larger than the width of the to-be-removed peripheral portion W in the radial direction and the non-bonding region Ae is formed up to an inner side than the target formation position of the peripheral modification layer M1 in the radial direction, the first wafer W may be spaced from the second wafer S after the removal of the peripheral portion We, which may cause the particle generation or the like in the subsequent process.

In this case, the combined wafer T is carried out from the inside of the interface modifying apparatus 50 by the wafer transfer device 40, and the next combined wafer T is carried into the interface modifying apparatus 50. The combined wafer T taken out from the interface modifying apparatus 50 is, for example, discarded or collected.

Meanwhile, if it is determined in the process St2 that the width of the formed non-bonding region Ae is smaller than the width of the to-be-removed peripheral portion We in the radial direction and the non-bonding region Ae is not formed up to a set position outer than the target formation position of the peripheral modification layer M1 in the radial direction or when it is determined that a part of the non-bonding region Ae is not formed, the peripheral portion We cannot be appropriately separated in that portion where the non-bonding region Ae is not formed, which raises a risk that a part of the peripheral portion We may be left in the combined wafer T.

In this case, the portion where the non-bonding region Ae is not formed is irradiated with the interface laser light L1 again, as shown in FIG. 7 (process St1). In other words, re-formation of the non-bonding region Ae in the peripheral portion We to be removed is performed. Furthermore, conditions for this re-formation of the non-bonding region Ae may be fed back to conditions for formation of the non-bonding region Ae (process St1) for the combined wafer T to be processed next in the wafer processing system 1.

The combined wafer T, for which it is determined that the non-bonding region Ae is appropriately formed in the entire surface of the peripheral portion We to be removed in the process St2, is then transferred to the internal modifying apparatus 60 by the wafer transfer device 40.

In the internal modifying apparatus 60, the combined wafer T held by the chuck 200 is first moved to a macro imaging position. The macro imaging position is a position where the macro camera 220 is capable of imaging the outer end of the first wafer W. At the macro imaging position, while rotating the chuck 200, the macro camera 220 images the outer end of the first wafer W in 360 degrees in the circumferential direction. The obtained image is outputted from the macro camera 220 to the control device 90.

The control device 90 calculates an eccentric amount between a rotation center of the chuck 200 and the center of the first wafer W from the image of the macro camera 220. Also, the control device 90 calculates a moving amount of the chuck 200 based on the calculated eccentric amount to correct a Y-axis component of the corresponding eccentric amount. The control device 90 moves the chuck 200 horizontally along the Y-axis direction based on this calculated moving amount. Additionally, the control device 90 specifies the position of an inner end of the non-bonding region Ae in the radial direction (hereinafter simply referred to as “inner end”), which has been formed in the interface modifying apparatus 50, from the image of the macro camera 220. Based on the inner end of the non-bonding region Ae detected by the macro camera 220, a radiation position of the internal laser light L2 is set to be slightly inside the inner end in the radial direction, for example.

Thereafter, the internal laser light L2 is radiated from the laser head 210 to the preset radiation position of the internal laser light L2 to form the peripheral modification layer M1 and the split modification layer M2 sequentially inside the first wafer W, as shown in FIG. 3 and FIG. 6B (process St3 in FIG. 7). The peripheral modification layer M1 serves as a starting point for removing the peripheral portion We in the edge trimming to be described later. The split modification layer M2 serves as a starting point for breaking the peripheral portion We to be removed into smaller pieces. Further, in the drawings to be referred to in the following description, illustration of the split modification layer M2 may be omitted in order to avoid complication of the illustration.

In forming the peripheral modification layer M1, inside the first wafer W, a crack C1 develops from the peripheral modification layer M1 in a thickness direction of the first wafer W. An upper end of the crack C1 reaches, for example, the front surface Wa, as illustrated in FIG. 6B.

Further, in the present exemplary embodiment, the formation position of the peripheral modification layer M1 is set to be slightly inside the inner end of the non-bonding region Ae in the radial direction. Accordingly, as illustrated in FIG. 6B, a lower end of the crack C1 develops from a lower end of the lowermost peripheral modification layer M1 toward the inner end of the non-bonding region Ae, for example.

Once the peripheral modification layer M1 and the split modification layer M2 are formed inside the first wafer W, it is then inspected whether or not the peripheral modification layer M1 has been appropriately formed inside the first wafer W, and, also, whether or not the crack C1 has developed (process St4 in FIG. 7). A detailed inspection method in the internal modifying apparatus 60 will be described later.

If it is determined in the process St4 that the peripheral modification layer M1 (crack C1) is not properly formed, the peripheral portion We may not be properly removed at the portion where the crack C1 is not extended, which raises a risk that a part of the peripheral portion We may be left in the combined wafer T.

In this case, the internal laser light L2 is radiated to the portion where the crack C1 is not formed. As a result, a new peripheral modification layer M1 is formed inside the first wafer W, allowing the crack C1 to develop between the inner end of the non-bonding region Ae and the lower end of the previous peripheral modification layer M1 via the new peripheral modification layer M1. In addition, conditions for the formation of this new peripheral modification layer M1 may be fed back for the conditions for forming the peripheral modification layer M1 (process St3) for the combined wafer T to be processed next in the wafer processing system 1.

Alternatively, in this case, the combined wafer T is carried out from the inside of the internal modifying apparatus 60 by the wafer transfer device 40, and the next combined wafer T is carried into the internal modifying apparatus 60. The combined wafer T taken out from the internal modifying apparatus 60 is discarded or collected, for example.

In the process St4, the combined wafer T, for which it is determined that the peripheral modification layer M1 (crack C1) has been appropriately formed inside the first wafer W, is then transferred to the periphery removing apparatus 70 by the wafer transfer device 40. In the periphery removing apparatus 70, the peripheral portion We of the first wafer W is removed, that is, the edge trimming is performed, as shown in FIG. 6C (process St5 in FIG. 7). At this time, the peripheral portion We is separated from the central portion Wc of the first wafer W starting from the peripheral modification layer M1 and the crack C1, and is separated from the central portion Wc of the first wafer W completely along the non-bonding region Ae. Also, the peripheral portion We being removed is broken into smaller pieces starting from the split modification layer M2.

In removing the peripheral portion We, a blade B (see FIG. 6C) formed in, for example, a wedge shape may be inserted into the interface between the first wafer W and the second wafer S forming the combined wafer T.

Once the peripheral portion We of the first wafer W is removed, inspection is then performed to determine whether the peripheral portion We has been properly removed from the first wafer W (process St6 in FIG. 7). A detailed inspection method in the periphery removing apparatus 70 will be explained later.

If it is determined in the process St6 that the peripheral portion We has not be properly formed, that is, if a part of the peripheral portion We remains in the combined wafer T, particle generation or the like may be caused in the subsequent process.

In this case, as shown in FIG. 7, the blade B may be inserted again (process St5) into the non-separated part of the peripheral portion We.

Alternatively, in this case, the combined wafer T may be carried out from the inside of the periphery removing apparatus 70 by the wafer transfer device 40 to be discarded or collected.

The combined wafer T, for which it is determined in the process St6 that the peripheral portion We of the first wafer W has been appropriately removed, is then transferred to the cleaning apparatus 80 by the wafer transfer device 40. In the cleaning apparatus 80, the first wafer W whose peripheral portion We has been removed, and/or the second wafer S are cleaned (process St7 in FIG. 7).

Afterwards, the combined wafer T after being subjected to all the required processes is transferred to the cassette C on the cassette placing table 10 by the wafer transfer device 20 via the transition device 30. In this way, the series of processes of the wafer processing in the wafer processing system 1 are completed.

Further, in the above-described exemplary embodiment, although the non-bonding region Ae in which the bonding strength between the first wafer W and the second wafer S is reduced and the peripheral modification layer M1 serving as the starting point for the separation of the peripheral portion We are formed in this order, the order for forming them is not particularly limited. That is, the non-bonding region Ae may be formed at the interface between the first wafer W and the second wafer S in the interface modifying apparatus 50 after the peripheral modification layer M1 is formed inside the first wafer W in the internal modifying apparatus 60.

Now, the inspection method of inspecting the non-bonding region Ae in the above-described interface modifying apparatus 50 (process St2 in FIG. 7 described above) will be described.

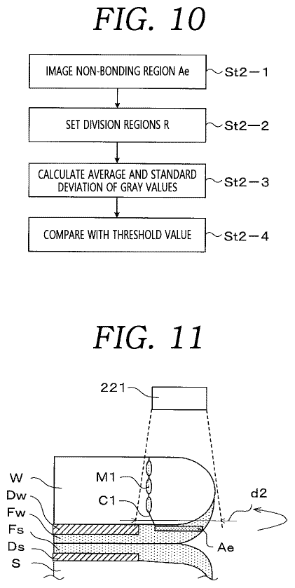

In the inspection of the non-bonding region Ae, first, as described in FIG. 8, while rotating the chuck 100, the non-bonding region Ae formed in the process St1 is imaged in 360 degrees in the circumferential direction by the micro camera 121 (process St2-1 in FIG. 10). The obtained image is outputted from the micro camera 121 to the control device 90.

An imaging width d1 of the non-bonding region Ae by the micro camera 121 in the radial direction is set to a width including at least a range from the outer end (edge) of the first wafer W to the inner end of the non-bonding region Ae.

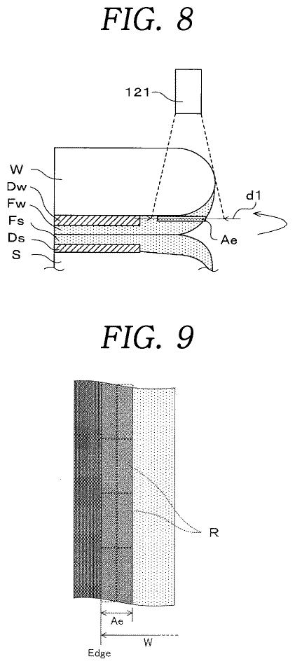

Further, in the obtained image, an outer side (outer region: left side in FIG. 9) than the outer end of the first wafer W is dark, whereas an inner side (inner region: right side in FIG. 9) than an inner end of the non-bonding region Ae is bright, as illustrated in FIG. 9, for example. In addition, the brightness of a region (intermediate region: center in FIG. 9) between the outer region and the inner region, where the non-bonding region Ae is formed, is approximately intermediate between the brightness of the outer region and the brightness of the inner region.

Upon receiving the output of the obtained image, the control device 90 divides, in the image of the non-bonding region Ae taken by the micro camera 121 in 360 degrees in the circumferential direction, the intermediate region, which is a portion where the non-bonding region Ae is formed, into a plurality of division regions R (see FIG. 9) in at least one of the radial direction and the circumferential direction (in the shown example, both in the radial direction and in the circumferential direction) (process St2-2 in FIG. 2).

Next, in each of the plurality of division regions R divided in the process St2-2, statistical values of gray values, for example, an average value (Mean) and a standard deviation (Sigma) are calculated (process St2-3 in FIG. 10).

Then, based on the average value and the standard deviation of the gray values calculated in the process St2-3, it is determined whether the non-bonding region Ae has been appropriately formed in the process St1 of FIG. 7, that is, whether the non-bonding region Ae has been appropriately formed around the entire circumference of the first wafer W and whether the formation width of the non-bonding region Ae is uniform around the entire circumference (process St2-4 in FIG. 10).

Specifically, when the non-bonding region Ae is appropriately formed with a uniform formation width around the entire circumference of the first wafer W, the average values and the standard values of the gray values obtained from the respective division regions R are assumed to be approximately the same.

Thus, in the present exemplary embodiment, when the average value and the standard deviation of the gray values calculated from each of the plurality of division regions R fall within preset threshold values, there is made a determination that the non-bonding region Ae is appropriately formed around the entire circumference of the first wafer W. The “threshold value” according to the present exemplary embodiment is a value set to allow appropriate separation of the peripheral portion We, and may be determined empirically based on a previous processing result of the combined wafer T.

Meanwhile, when there is detected a division region R that becomes a singularity where either the average value or the standard deviation of the gray values deviates from the threshold value, there is made a determination that the non-bonding region Ae is not properly formed in that division region R which is the singularity.

Specifically, when the division region R which becomes the singularity where the average value or the standard deviation of the gray values deviates from the threshold value is detected as stated above, it is determined that the interface laser beam L1 has not been focused on the interface between the first wafer W and the second wafer S in the division region R as the singularity due to such a factor as occurrence of passing light, so the non-bonding region Ae could not be appropriately formed thereat.

If the non-bonding region Ae is formed at the same height inside the combined wafer T, the infrared light from the micro camera 121 would be received by being reflected in the non-bonding region Ae, that is, at the same height inside the combined wafer T. That is, if the infrared light is reflected at the same height, the calculated gray value would become approximately constant.

Thus, when the non-bonding region Ae is not properly formed in a part of the circumferential direction or radial direction of the first wafer W due to the influence of, for example, the occurrence of the passing light, specifically, when the non-bonding region Ae is not formed at the same height at least, the reflection height of the infrared light from the micro camera 121 changes, so that the average value or the standard deviation calculated from the gray values is also changed. Thus, the inappropriate formation of the non-bonding region Ae can be detected.

If it is determined in the process St2-4 that the non-bonding region Ae is not properly formed, the combined wafer T is discarded or collected, or the non-bonding region Ae is formed again, as stated above. Meanwhile, when it is determined that the non-bonding region Ae is properly formed, the series of processes of the inspection of the non-bonding region Ae are completed, and the combined wafer T is carried out from the interface modifying apparatus 50.

According to the present exemplary embodiment, based on the gray values of the image taken by the near-infrared camera, the non-bonding region Ae formed at the interface of the first wafer W and the second wafer S (modification state inside the combined wafer T) can be inspected in a non-destructive way. In other words, prior to the removing (edge trimming) of the peripheral portion We of the first wafer W, the forming state of the non-bonding region Ae can be inspected in advance. Accordingly, in case that the non-bonding region Ae for reducing the bonding strength between the first wafer W and the second wafer S is not properly formed, the separation of the peripheral portion We may not be performed, and it may be possible to determine whether to re-form the non-bonding region Ae or whether to discard or collect the combined wafer T in which the inappropriate non-bonding region Ae is formed. As a result, the proportion of waste wafers in the wafer processing system 1 can be reduced, or throughput can be improved.

Additionally, according to the present exemplary embodiment, the forming state of the non-bonding region Ae can be simply inspected by imaging, with the micro camera 121, the peripheral portion We of the first wafer W where the non-bonding region Ae is formed, and then by comparing the average value or the standard deviation of the gray values calculated by the control device 90 with the preset threshold value. As the inspection can be simply carried out through the comparison of the calculated values in this way, it is also easy to automatically control the inspection of the forming state of the non-bonding region Ae by the control device 90.

Furthermore, in the above-described exemplary embodiment, the forming state of the non-bonding region Ae is inspected by comparing at least one of the average value and the standard deviation of the calculated gray values with the preset threshold value. However, a comparison reference with which these parameters are compared is not limited to the predetermined threshold value.

By way of example, instead of setting the threshold value for the comparison in advance, a parameter used for, among the other combined wafers T for which the imaging of the peripheral portion We (calculation of a parameter) has been performed prior to the combined wafer T currently being inspected, the combined wafer T in which the non-bonding region Ae is appropriately formed and the peripheral portion We is properly separated may be used as the comparison reference. In other words, a processing result of another combined wafer T may be set as the threshold value and fed back to the processing conditions for the combined wafer T that is being currently processed.

Moreover, instead of using the parameter of another combined wafer T or the preset threshold value as the comparison reference, the gray values acquired within the same plane of the combined wafer T to be inspected, that is, in the plurality of division regions R may be compared with each other.

However, when comparing the gray values within the same plane of the combined wafer T with each other in this way, if the non-bonding region Ae has not been properly formed in the entire surface and around the entire circumference of the peripheral portion We, that is, if the non-bonding region Ae has not been formed in the same manner in all of the divisions regions R, there is a risk that the forming state of the non-bonding region Ae cannot be properly inspected because there is no difference in the results of the mutual comparisons. Taking this into account, as described in the above exemplary embodiment, it is desirable to set the threshold value as the comparison reference in advance.

In addition, in the above-described exemplary embodiment, although the inspection is carried out by imaging the non-bonding region Ae with the micro camera 121 provided inside the interface modifying apparatus 50, an imaging device configured to image the non-bonding region Ae is not particularly limited as long as it is a camera capable of imaging the non-bonding region Ae appropriately. By way of example, if the macro camera 120 used to image the outer end of the first wafer W can be used to image the non-bonding region Ae as well, the micro camera 121 may be omitted from the interface modifying apparatus 50.

Alternatively, instead of performing the inspection inside the interface modifying apparatus 50, the inspection of the non-bonding region Ae (process St2) may be performed by using an inspection device (not shown) independently provided outside the interface modifying apparatus 50.

Now, the inspection method of inspecting the forming state of the peripheral modification layer M1 and the state of the development of the crack C1 (process St4 in FIG. 7 described above) will be explained.

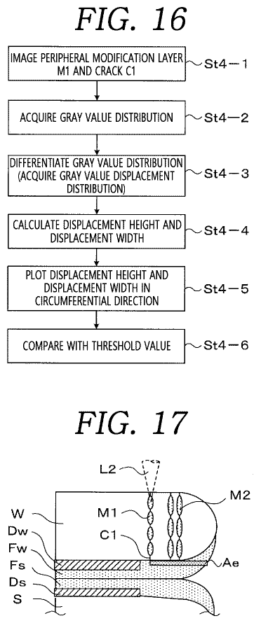

In the inspection in the internal modifying apparatus 60, first, as illustrate in FIG. 11, while rotating the chuck 200, the peripheral modification layer M1 and the crack C1 formed in the process St3 are imaged in 360 degrees in the circumferential direction by the micro camera 221 (process St4-1 in FIG. 16). The taken image is outputted from the micro camera 221 to the control device 90.

An imaging width d2 in the radial direction by the micro camera 221 is set to a width including at least a range from the outer end (edge) of the first wafer W to the peripheral modification layer M1 and the crack C1 formed inside the first wafer W.

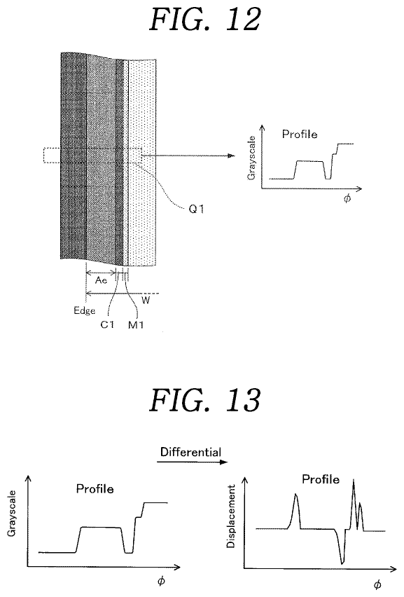

Further, in the obtained image, an outer side (outer region: left side in FIG. 12) than the outer end of the first wafer W is dark, whereas an inner side (inner region: right side in FIG. 12) than the formation position of the peripheral modification layer M1 is bright, as illustrated in FIG. 12, for example. In addition, the brightness of a portion (intermediate region: next to the outer region in FIG. 12) where the non-bonding region Ae is formed is approximately intermediate between the brightness of the outer region and the brightness of the inner region. Moreover, the brightness of a portion (next to the inner region in FIG. 12) where the peripheral modification layer M1 is formed is approximately intermediate between the brightness of the intermediate region and the brightness of the inner region because the infrared light is reflected from the peripheral modification layer M1 formed at the uppermost end in the first wafer W. Additionally, a portion where the crack C1 extending between the lower end of the peripheral modification layer M1 and the inner end of the non-bonding region Ae (that is, a portion between the intermediate region and the portion where the peripheral modification layer M1 is formed in FIG. 12) is formed becomes approximately as dark as the outer region because the infrared light radiated by a coaxial vertical illumination method is not reflected toward the micro camera 221.

In other words, due to the formation of the peripheral modification layer M1 and the crack C1, a dark region (crack C1) and a region (peripheral modification layer M1) with brightness approximately intermediate between the brightness of the intermediate region and the brightness of the inner region are formed in the image taken by the micro camera 221, as compared to the image taken by the micro camera 121 in the above-described process St2-1.

In the control device 90, in the image of the peripheral modification layer M1 and the crack C1 taken in 360 degrees in the circumferential direction by the micro camera 221, there is acquired a profile of a gray value distribution in one rectangular region Q1, which is a part within 360 degrees in the circumferential direction and extends in the radial direction of the first wafer W, as shown in FIG. 12 (process St4-2 in FIG. 16).

In the gray value distribution, the gray value changes rapidly at a boundary between the outer region and the intermediate region, a boundary between the intermediate region the portion where the crack C1 is formed, a boundary between the portion where the crack C1 is formed and the portion where the peripheral modification layer M1 is formed, and a boundary between the portion where the peripheral modification layer M1 is formed and the inner region.

Next, the gray value distribution (vertical axis in FIG. 12) of the one rectangular region Q1 acquired in the process St4-2 is differentiated by a radial position of the first wafer W (horizontal axis in FIG. 12) (process St4-3 in FIG. 16).

As a result, a displacement of the gray value in the radial direction in the one rectangular region Q1 shown in FIG. 12 is calculated, and a profile of a displacement distribution of the gray value having peaks at the boundaries between the respective regions described above is obtained, as shown in FIG. 13.

Subsequently, based on the displacement distribution of the one rectangular region Q1 acquired in the process St4-3, a displacement height (EdgeHeight) and a displacement width (EdgeWidth) in the one rectangular region Q1 shown in FIG. 13 are calculated (process St4-4 in FIG. 16).

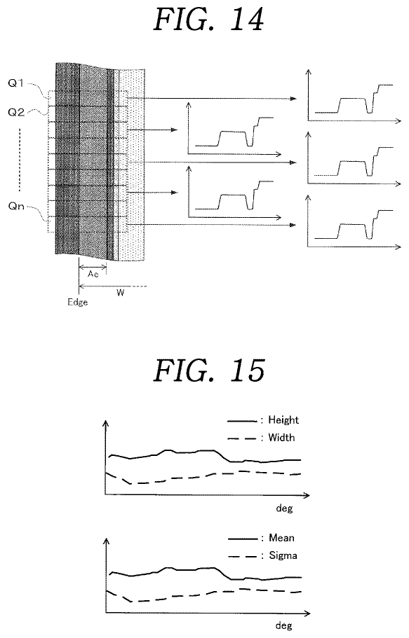

Further, the profile of the gray value distribution based on the image taken by the micro camera 221 is acquired in 360 degrees in the circumferential direction of the first wafer W. In other words, as shown in FIG. 14, in each of a plurality of rectangular regions Q1, Q2, . . . , Qn set side by side in the circumferential direction of the first wafer W, an average value and a standard deviation of gray values in the aforementioned gray value distribution, and a displacement height and a displacement width in the displacement distribution are acquired.

Then, the average value and the standard deviation of the gray values, and the displacement height and the displacement width of the gray value displacement obtained in each of the plurality of rectangular regions Q1, Q2, . . . , Qn are graphed with 360 degrees of the circumferential position of the first wafer W taken as a horizontal axis, as shown in FIG. 15 (process St4-5 in FIG. 16).

Next, based on a relationship between the displacement height and the displacement width of the gray value displacement and the circumferential position of the first wafer W, it is detected whether the peripheral modification layer M1 has been formed around the entire circumference of the first wafer W, and, also, whether the crack C1 has appropriately developed around the entire circumference of the first wafer W in the process St3 in FIG. 7 (process St4-6 in FIG. 16).

Specifically, when the peripheral modification layer M1 (crack C1) is appropriately formed around the entire circumference of the first wafer W, it is assumed that the displacement heights and the displacement widths of the gray value displacements acquired in the plurality of rectangular regions Q1, Q2, . . . , Qn show the same tendency. In other words, it is assumed that the displacement height and the displacement width of the gray value displacement change constantly regardless of the circumferential position of the first wafer W.

In the present exemplary embodiment, when the displacement height and the displacement width of this gray value displacement fall within a preset threshold value (second threshold value) in the entire circumference of the first wafer W, there is made a determination that the peripheral modification layer M1 and the crack C1 are appropriately formed around the entire circumference of the first wafer W.

Meanwhile, when either the displacement height or the displacement width of the gray value displacement has a singularity that falls beyond the threshold value, there is made a determination that the peripheral modification layer M1 or the crack C1 is not appropriately formed at a circumferential position corresponding to the singularity.

Specifically, when a singularity that falls beyond the threshold value is detected in the displacement height of the gray value displacement, it is determined that the peripheral modification layer M1 or the crack C1 has not be properly formed.

This is because, when the peripheral modification layer M1 is appropriately formed around the entire circumference of the first wafer W, a reflection position (reflection height) of the infrared light from the micro camera 121 becomes approximately constant. In addition, it is also because, when the crack C1 is properly formed around the entire circumference of the first wafer W, reflection of the infrared light from the micro camera 121 is not detected around the entire circumference of the first wafer W.

For this reason, if the peripheral modification layer M1 is not properly formed in a part of the circumferential direction, for example, the measured gray value of the infrared light changes, and the displacement height of the displacement distribution is shifted, which implies that at least the peripheral modification layer M1 formed at the uppermost end in the thickness direction of the first wafer W is not properly formed. Also, when the crack C1 is not properly extended in a part of the circumferential direction, reflection of the infrared light is detected in that part of the circumferential direction, so that the inappropriate development of the crack C1 can be detected.

In addition, when a singularity that falls beyond the threshold value is detected in the displacement width of the gray value displacement, it is determined that the crack C1 is not properly formed.

This is because, when the crack C1 is appropriately extended in the entire circumference of the first wafer W, a non-reflection width of the infrared light from the micro camera 121 becomes constant. That is, it is because, when the width beyond which reflection of the infrared light cannot be detected is constant, the calculated displacement width becomes approximately constant.

Thus, when the displacement width of the gray value is changed due to a change in the non-reflection width of the infrared light, a peak position of the displacement distribution is deviated. In view of this, it can be detected that the extension width of the crack C1 is not constant, that is, the crack C1 is not extended appropriately.

If it is determined in the process St4-6 that the peripheral modification layer M1 or the crack C1 is not properly formed, the combined wafer T is discarded or collected, or the peripheral modification layer M1 or the crack C1 is re-formed. In this case, the conditions for the formation of the peripheral modification layer M1 and the crack C1 may be feedback-controlled to processing conditions for the combined wafer T to be processed next in the wafer processing system 1. Meanwhile, when it is determined that the non-bonding region Ae is properly formed, the series of processes for the inspection of the peripheral modification layer M1 and the crack C1 are ended, and the combined wafer T is carried out of the internal modifying apparatus 60.

According to the present exemplary embodiment, based on the gray value of the image taken by the near-infrared camera, the peripheral modification layer M1 and the crack C1 formed inside the first wafer W can be inspected in a non-destructive way. In other words, prior to the removing (edge trimming) of the peripheral portion We of the first wafer W, the forming state of the peripheral modification layer M1 and the crack C1 can be inspected in advance. Accordingly, in case that the peripheral modification layer M1 or crack C1 to be used as the starting point for the separation of the peripheral portion We is not properly formed, the separation of the peripheral portion We may not be performed, and it may be possible to determine whether to re-form the peripheral modification layer M1 or the crack C1 or whether to discard or collect the combined wafer T. As a result, the proportion of waste wafers generated in the wafer processing system 1 can be reduced, or the throughput can be improved.

In addition, in the present exemplary embodiment, although it is inspected whether the peripheral modification layer M1 and the crack C1 have been properly formed in the process St4, the inspection by the infrared light cannot be performed for the plurality of peripheral modification layers M1 formed in the thickness direction of the first wafer W as stated above, except the peripheral modification layer M1 formed at the uppermost end in the thickness direction.

Taking this into consideration, in the process St4, the inspection of the peripheral modification layer M1 may be omitted, and only the development of the crack C1 may be inspected.

In addition, in the above-described exemplary embodiment, the formation position of the peripheral modification layer M1 is set to be slightly inner side than the inner end of the non-bonding region Ae in the radial direction, thus allowing the formation of the crack C1 extending diagonally upwards from the inner end of the non-bonding region Ae. However, the peripheral modification layer M1 may be formed at a position corresponding to the inner end of the non-bonding region Ae in the radial direction, as illustrated in FIG. 17.

In this case, since the crack C1 does not develop diagonally upwards inside the first wafer W, the above-described process St4, that is, the inspection of the peripheral modification layer M1 and the crack C1 may be omitted.

Further, in the above-described exemplary embodiment, the inspection is carried out by imaging the peripheral modification layer M1 and the crack C1 with the micro camera 221 provided inside the internal modifying apparatus 60. However, the macro camera 220 may be used as the imaging mechanism configured to image the peripheral modification layer M1 and the crack C1. In this case, the micro camera 221 may be omitted from the internal modifying apparatus 60.

Alternatively, instead of performing the inspection inside the internal modifying apparatus 60, the peripheral modification layer M1 and the crack C1 may be inspected by using an inspection device (not shown) independently provided outside the internal modifying apparatus 60. In this case, in the inspection device that inspects the peripheral modification layer M1 and the crack C1, the inspection of the above-described non-bonding region Ae may be further performed.

Now, the inspection method of inspecting the state of the removal of the peripheral portion We (process St6 in FIG. 7 described above) will be explained.

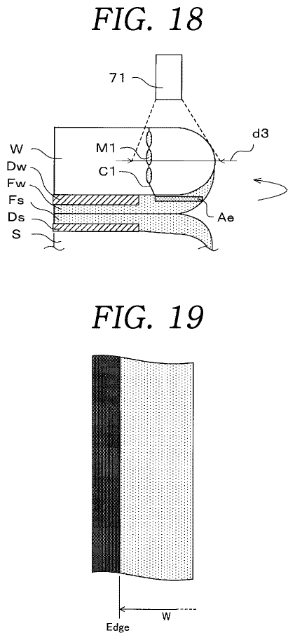

In the inspection in the periphery removing apparatus 70, while rotating a non-illustrated chuck, the outer end of the first wafer W before being subjected to the removal of the peripheral portion We is imaged in 360 degrees in the circumferential direction by the imaging mechanism 71 (for example, a CCD camera), as illustrated in FIG. 18 (process St6-0 in FIG. 23). In other words, in the periphery removing apparatus 70, the imaging of the first wafer W is performed prior to the process St5 (edge trimming) shown in FIG. 7. The obtained image is outputted to the control device 90.

An imaging width d3 in the radial direction by the imaging mechanism 71 is set to a width including at least a range from the outer end (edge) of the first wafer W to the inner end of the peripheral portion We to be removed (formation position of the peripheral modification layer M1).

In the process St6-0, the rear surface Wb of the first wafer W before being subjected to the removal of the peripheral portion We is imaged by the imaging mechanism 71. In the obtained image, an outer side than the outer end of the first wafer W is darker, and an inner side than the outer end of the first wafer W is bright, as shown in FIG. 19.

Next, the removal of the peripheral portion We, that is, the edge trimming is performed by inserting the blade B formed in, for example, the wedge shape into the interface between the first wafer W and the second wafer S forming the combined wafer T (see FIG. 6C) (process St5 in FIG. 7 and FIG. 23).

Once the peripheral portion We of the first wafer W is removed, while rotating the non-illustrated chuck, the outer end of the first wafer W after being subjected to the removal of the peripheral portion We is imaged in 360 degrees in the circumferential direction by the imaging mechanism 71 (for example, a CCD camera), as illustrated in FIG. 20 (process St6-1 in FIG. 23). The taken image is outputted to the control device 90.

Desirably, an imaging width in the radial direction by the imaging mechanism 71 in the process St6-1 is the same as the imaging width d3 before the removal of the peripheral portion We in the process St6-0.

In addition, in the taken image, as shown in FIG. 21, an outer side (outer region: left side in FIG. 21) than the outer end of the first wafer W is dark, and an inner side (inner region: right side in FIG. 21) than the outer end of the first wafer W after being subjected to the removal of the peripheral portion We, that is, a separation surface of the peripheral portion We in the radial direction is bright. Further, brightness of a portion (intermediate region) which is an exposed surface of the second wafer S (bonding film Fw in the shown example) exposed by the removal of the peripheral portion We is approximately intermediate between the brightness of the outer region and the brightness of the inner region. Moreover, an inclined portion (between the inner region and the intermediate region) corresponding to the formation position of the crack C1 becomes approximately as dark as the outer region.

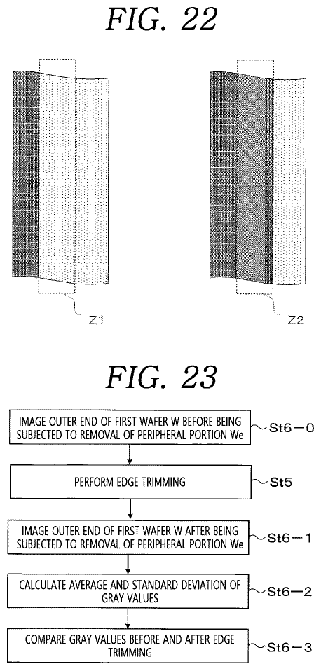

Next, from the image of the outer end of the first wafer W taken in 360 degrees in the circumferential direction in each of the processes St6-0 and St6-1, the control device 90 calculates statistical values of gray values, for example, an average value (Mean) and a standard deviation (Sigma) in an annular region (see annular regions Z1 and Z2 in FIG. 22) corresponding to the peripheral portion We (process St6-2 in FIG. 23).

Then, based on the average value and the standard deviation of the gray values calculated in the process St6-2, it is detected whether the peripheral portion We has been appropriately removed from the first wafer W in the edge trimming of the process St5 (process St6-3 in FIG. 23).

Specifically, a difference in the gray values of the outer end (annular regions Z1 and Z2) of the first wafer W before and after the removal of the peripheral portion We obtained in the process St6-2 is calculated.

When the peripheral portion We is appropriately removed around the entire circumference of the first wafer W, the gray value of the annular region Z2 obtained from the imaging result after the removal of the peripheral portion We is assumed to be changed from the gray value of the annular region Z1 obtained from the imaging result before the removal of the peripheral portion We.

Thus, in the present exemplary embodiment, when the change in the gray value in the annular regions Z1 and Z2 is detected around the entire circumference of the first wafer W, there is made a determination that the peripheral portion We has been appropriately removed all around the first wafer W.

Meanwhile, if there is no change in the gray value in a part of the circumferential direction of the first wafer W, for example, it is deemed that the peripheral portion We is not appropriately removed in that part where the gray value has not changed.

If it is determined in the process St6-3 that the peripheral portion We has not been appropriately removed, the blade B is inserted again into the unseparated portion of the peripheral portion We as described above. Alternatively, the combined wafer T is taken out from the inside of the periphery removing apparatus 70 to be discarded or collected. On the other hand, when it is determined that the peripheral portion We has been appropriately removed, a series of processes for inspecting the state of the removal of the peripheral portion We are completed, and the combined wafer T is carried out of the periphery removing apparatus 70.

According to the present exemplary embodiment, based on the gray value of the image taken by the imaging mechanism 71, it is possible to automatically inspect whether or not the peripheral portion We has been appropriately removed from the first wafer W without an operator's judgement. As a result, the throughput in the wafer processing system 1 can be improved.

In addition, in the above-described exemplary embodiment, whether the peripheral portion We has been appropriately removed is inspected by comparing the gray values obtained from the images taken inside the periphery removing apparatus 70 before and after the edge trimming. However, the inspection method is not limited thereto.

Specifically, instead of comparing the gray value obtained from the image taken after the edge trimming with the gray value obtained from the image taken before the edge trimming, whether the peripheral portion We has been appropriately removed may be inspected by using a threshold value (third threshold value) obtained and set in advance when the peripheral portion We has been appropriately removed, in other words, set based on an edge trimming result of another combined wafer T as a comparison reference. In this case, imaging of the outer end of the first wafer W before the edge trimming in the periphery removing apparatus 70 (process St6-0 in FIG. 23) may be appropriately omitted.

In addition, in the above-described exemplary embodiment, although the inspection is performed inside the periphery removing apparatus 70, the inspection may be performed by using an inspection device (not shown) provided independently outside the periphery removing apparatus 70. In this case, in the inspection device that inspects the state of the removal of the peripheral portion We, inspection of the above-described non-bonding region Ae and/or inspection of the above-described peripheral modification layer M1 and crack C1 may be further carried out.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Wafer processing system
50: Interface modifying apparatus
60: Internal modifying apparatus
70: Periphery modifying apparatus
90: Control device
121: Micro camera
Ae: Non-bonding region
L1: Interface laser light
M1: Peripheral modification layer
S: Second wafer
T: Combined wafer
W: First wafer
We: Peripheral portion

1. A processing method of processing a combined substrate in which a first substrate and a second substrate are bonded to each other, the processing method comprising:
forming, by radiating laser light to an interface between the first substrate and the second substrate, a non-bonding region with reduced bonding strength at the interface;
inspecting a forming state of the non-bonding region;
forming a peripheral modification layer along a boundary between a peripheral portion of the first substrate and a central portion of the first substrate; and
removing the peripheral portion starting from the peripheral modification layer,
wherein the inspecting of the forming state of the non-bonding region comprises:
imaging the non-bonding region by using a camera;
acquiring, from an obtained image of the non-bonding region, a distribution of gray values in a plan view of the non-bonding region; and
inspecting the forming state of the non-bonding region by comparing the acquired gray values with a preset threshold value.

2. The processing method of claim 1,
wherein in the inspecting of the forming state of the non-bonding region, the distribution of the gray values is acquired for each of multiple division regions arranged in at least one of a circumferential direction or a radial direction of the first substrate.

3. The processing method of claim 2, further comprising:
comparing the gray values acquired for the respective multiple division regions with each other.

4. The processing method of claim 1,
wherein a parameter of the gray values to be compared with the threshold value includes at least one of an average value and a standard deviation of the gray values obtained from the obtained image.

5. The processing method of claim 1,
wherein in the forming of the peripheral modification layer, a crack extending between the peripheral modification layer and the non-bonding region is formed inside the first substrate, and
the processing method further comprises:
inspecting a forming state of at least one of the peripheral modification layer or the crack.

6. The processing method of claim 5,
wherein the inspecting of the forming state of the peripheral modification layer or the crack comprises:
imaging the peripheral modification layer and the crack by using a camera;
acquiring, from an obtained image of the peripheral modification layer and the crack, a distribution of gray values in a plan view of the first substrate; and
inspecting whether or not the peripheral modification layer or the crack is formed around an entire circumference of the first substrate by comparing the acquired gray value with a preset second threshold value.

7. The processing method of claim 6,
wherein a parameter of the gray values to be compared with the second threshold value includes at least one of an average value and a standard deviation of the gray values obtained from the obtained image, or a height and a radial-directional width of a gray value displacement distribution.

8. The processing method of claim 1, further comprising:
inspecting whether the peripheral portion, which is a removal target, is removed from the combined substrate,
wherein the inspecting of whether the peripheral portion is removed comprises:
imaging, by using a camera, an end of the first substrate after the peripheral portion is removed;
acquiring, from an obtained image of the end of the first substrate after the peripheral portion is removed, a distribution of gray values at a position corresponding to the peripheral portion in a plan view of the first substrate; and
inspecting whether the peripheral portion is removed around an entire circumference of the first substrate by comparing the distribution of the gray values, obtained after the peripheral portion is removed, with a preset third threshold value.

9. The processing method of claim 8, further comprising:
imaging, by using a camera, the end of the first substrate before the peripheral portion is removed; and
acquiring, from an obtained image of the end of the first substrate before the peripheral portion is removed, a distribution of gray values at the position corresponding to the peripheral portion in the plan view of the first substrate,
wherein the third threshold value is the distribution of the gray values acquired from the obtained image of the end of the first substrate before the peripheral portion is removed.

10. A processing system configured to process a combined substrate in which a first substrate and a second substrate are bonded to each other, the processing system comprising:
an interface modifying apparatus configured to form, by radiating laser light to an interface between the first substrate and the second substrate, a non-bonding region with reduced bonding strength at the interface;
an inspection device configured to inspect a forming state of the non-bonding region;
an internal modifying apparatus configured to form a peripheral modification layer along a boundary between a peripheral portion of the first substrate and a central portion of the first substrate;
a periphery removing apparatus configured to remove the peripheral portion starting from the peripheral modification layer; and
a control device and a program storage including a program,
wherein in inspection by the inspection device, the program storage and the program are configured, with the control device, to perform:
imaging the non-bonding region by using a camera;
acquiring, from an obtained image of the non-bonding region, a distribution of gray values in a plan view of the non-bonding region; and
comparing the acquired gray values with a preset threshold value.

11. The processing system of claim 10,
wherein in the inspection by the inspection device, the control device performs acquiring the distribution of the gray values for each of multiple division regions arranged in at least one of a circumferential direction or a radial direction of the first substrate.

12. The processing system of claim 11,
wherein the control device compares the gray values acquired for the respective multiple division regions with each other.

13. The processing system of claim 10,
wherein a parameter of the gray values to be compared with the threshold value includes at least one of an average value or a standard deviation of the gray values obtained from the obtained image.

14. The processing system of claim 10,
wherein the control device performs:
operating, in forming the peripheral modification layer, the internal modifying apparatus such that a crack develops between the peripheral modification layer and the non-bonding region inside the first substrate; and
operating the inspection device to inspect a forming state of at least one of the peripheral modification layer or the crack.

15. The processing system of claim 14,
wherein in inspection of the peripheral modification layer or the crack, the control device performs:
imaging the peripheral modification layer and the crack by using a camera;
acquiring, from an obtained image of the peripheral modification layer and the crack, a distribution of gray values in a plan view of the first substrate; and
comparing the acquired gray values with a preset second threshold value.

16. The processing system of claim 15,
wherein a parameter of the gray values to be compared with the second threshold value includes at least one of an average value and a standard deviation of the gray values obtained from the obtained image, or a height and a radial-directional width of a gray value displacement distribution.

17. The processing system of claim 10,
wherein the control device performs:
operating the inspection device to inspect whether the peripheral portion, which is a removal target, is removed from the combined substrate,
wherein in inspection of a removal state of the peripheral portion, the control device performs:
imaging, by using a camera, an end of the first substrate after the peripheral portion is removed;
acquiring, from an obtained image of the end of the first substrate after the peripheral portion is removed, a distribution of gray values at a position corresponding to the peripheral portion in a plan view of the first substrate; and
comparing the distribution of the gray values, obtained after the peripheral portion is removed, with a preset third threshold value.

18. The processing system of claim 17,
wherein in the inspection of the removal state of the peripheral portion, the control device performs:
imaging, by using a camera, the end of the first substrate before the peripheral portion is removed; and
acquiring, from an obtained image of the end of the first substrate before the peripheral portion is removed, a distribution of gray values at the position corresponding to the peripheral portion in the plan view of the first substrate, and
wherein the distribution of the gray values acquired from the obtained image of the end of the first substrate before the peripheral portion is removed is used as the third threshold value.
